(19) United States
(12) Patent Application Publication
(10) Pub. No.: US 2025/0201536 A1
(43) Pub. Date: Jun. 19, 2025

(54) PLASMA PROCESSING METHOD AND PLASMA PROCESSING SYSTEM

(71) Applicant: Tokyo Electron Limited, Tokyo (JP)

(72) Inventor: Mitsuhiro IWANO, Miyagi (JP)

(73) Assignee: Tokyo Electron Limited, Tokyo (JP)

(21) Appl. No.: 19/059,760

(22) Filed: Feb. 21, 2025

Related U.S. Application Data
(63) Continuation of application No. PCT/JP2023/029817, filed on Aug. 18, 2023.

(30) Foreign Application Priority Data
Aug. 23, 2022 (JP) 2022-132627

(51) Int. Cl. H01J 37/32; H01L 21/311

(52) U.S. Cl. CPC H01J 37/32697; H01J 37/3244; H01L 21/31116; H01L 21/31144; H01J 2237/3346

(57) ABSTRACT

A plasma processing method includes: (a) preparing a substrate having an etching film and a dielectric film; (b) etching the etching film by repeatedly executing, a plurality of times, a cycle including (b-a) supplying a processing gas containing at least a carbon-containing gas into the chamber and forming a protective film at least on the dielectric film, and (b-b) supplying a processing gas containing at least a noble gas into the chamber; and (c) etching the etching film by executing, one or more times, a cycle including (c-a) supplying a processing gas containing at least a carbon-containing gas into the chamber, and (c-b) supplying a processing gas containing at least a noble gas into the chamber and supplying a bias signal to the substrate support.

### CROSS-REFERENCE TO RELATED APPLICATIONS

This application is a continuation application of International Patent Application No. PCT/JP2023/029817, filed on Aug. 18, 2023, which claims priority from Japanese Patent Application No. 2022-132627, filed on Aug. 23, 2022, with the Japan Patent Office, the disclosures of each are incorporated herein in their entireties by reference.

### TECHNICAL FIELD

The present disclosure relates to a plasma processing apparatus and a plasma processing system.

### BACKGROUND

Japanese Patent Laid-Open Publication No. 2016-136616 discloses a technique for improving the selection ratio for a dielectric film.

### SUMMARY

An embodiment of the present disclosure provides a plasma processing method executed in a plasma processing apparatus including a chamber and a substrate support unit disposed within the chamber. The plasma processing method includes: (a) preparing a substrate including an etching film and a dielectric film on the substrate support unit, the substrate having a first region where the etching film is exposed and a second region surrounding the first region, and the dielectric film being disposed in the second region; (b) etching the etching film by repeatedly executing, a plurality of times, a cycle multiple including (b-a) supplying a processing gas containing at least a carbon-containing gas into the chamber to generate a plasma and forming a protective film at least on the dielectric film, and (b-b) supplying a processing gas containing at least a noble gas into the chamber to generate a plasma and supplying a bias signal to the substrate support unit to etch at least a portion of the protective film and the etching film; and (c) etching the etching film by executing, one or more times, a cycle including (c-a) supplying a processing gas containing at least a carbon-containing gas into the chamber to generate a plasma and forming a protective film at least on the dielectric film, and (c-b) supplying a processing gas containing at least a noble gas into the chamber to generate a plasma and supplying a bias signal to the substrate support unit to etch at least a portion of the protective film and the etching film. In (b), the effective value of power or the absolute value of DC voltage of the bias signal supplied to the substrate support unit in an (N+1)^{th} cycle (N is an integer of 1 or more) in (b-b) is greater than the effective value of power or the absolute value of DC voltage of the bias signal supplied to the substrate support unit in an N^{th} cycle in (b-b), and the effective value of power or the absolute value of DC voltage of the bias signal supplied to the substrate support unit in (c-b) is equal to or greater than the effective value of power or the absolute value of DC voltage of the bias signal in (b-b).

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating a configuration example of a capacitively-coupled plasma processing apparatus.

FIG. 2 is a flowchart illustrating a present processing method.

FIG. 3 is a timing chart illustrating changes in bias power in the present processing method.

FIG. 4 is a view illustrating an example of the cross-sectional structure of a substrate W placed on a substrate support unit 11.

FIG. 5 is a view illustrating an example of the cross-sectional structure of the substrate W after execution of step ST1.

FIG. 6A is a view illustrating an example of the cross-sectional structure of the substrate W after execution of step ST2.

FIG. 6B is a view illustrating an example of the cross-sectional structure of the substrate W after execution of step ST3.

FIG. 7A is a view illustrating an example of the cross-sectional structure of the substrate W after execution of step ST4.

FIG. 7B is a view illustrating an example of the cross-sectional structure of the substrate W after execution of step ST5.

FIG. 8 is a view illustrating an example of the cross-sectional structure of the substrate W after execution of step ST7.

FIG. 9A is a timing chart illustrating an example of the bias power in the present processing method.

FIG. 9B is a timing chart illustrating an example of the bias power in the present processing method.

FIG. 9C is a timing chart illustrating an example of the bias power in the present processing method.

FIG. 10A is a timing chart illustrating the details of a cycle.

FIG. 10B is a timing chart illustrating the details of a cycle.

FIG. 10C is a timing chart illustrating the details of a cycle.

FIG. 11 is a view illustrating another example of the cross-sectional structure of a substrate W to which the present processing method is applicable.

FIG. 12A is a view illustrating another example of the cross-sectional structure of the substrate W on which a protective film is formed using the present processing method.

FIG. 12B is a view illustrating another example of the cross-sectional structure of the substrate W on which etching is performed using the present processing method.

### DETAILED DESCRIPTION

In the following detailed description, reference is made to the accompanying drawings which form a part hereof. The illustrative embodiments described in the detailed description, drawings, and claims are not meant to be limiting. Other embodiments may be utilized, and other changes may be made without departing from the spirit or scope of the subject matter presented herein.

Hereinbelow, each embodiment of the present disclosure will be described.

In an embodiment, provided is a plasma processing method performed in a plasma processing apparatus including a chamber and a substrate support unit disposed in the chamber, the plasma processing method comprising: (a) preparing a substrate including an etching film and a dielectric film on the substrate support unit, the substrate including a first region where the etching film is exposed and a second region surrounding the first region, and the dielectric film being disposed in the second region; (b) etching the etching film by repeatedly executing, a plurality of times, a cycle including: (b-a) supplying a processing gas containing at least a carbon-containing gas into the chamber to generate a plasma and forming a protective film at least on the dielectric film, and (b-b) supplying a processing gas containing at least a noble gas into the chamber to generate a plasma and supplying a bias signal to the substrate support unit to etch at least a portion of the protective film and the etching film; and (c) etching the etching film by executing, one or more times, a cycle including: (c-a) supplying a processing gas containing at least a carbon-containing gas into the chamber to generate a plasma and forming a protective film at least on the dielectric film, and (c-b) supplying a processing gas containing at least a noble gas into the chamber to generate a plasma and supplying a bias signal to the substrate support unit to etch at least a portion of the protective film and the etching film. In (b), an effective value of power or an absolute value of DC voltage of the bias signal supplied to the substrate support unit in an (N+1)^{th} cycle (N is an integer of 1 or more) in (b-b) is greater than an effective value of power or an absolute value of DC voltage of the bias signal supplied to the substrate support unit in an N^{th} cycle in (b-b), and an effective value of power or an absolute value of DC voltage of the bias signal supplied to the substrate support unit in (c-b) is equal to or greater than an effective value of power or the absolute value of DC voltage of the bias signal in (b-b).

In an embodiment, the substrate has a mask film formed on the etching film such that the etching film is partially exposed, and wherein, in (a), the etching film is etched by repeatedly executing, a plurality of times, a cycle including: (a-a) supplying a processing gas containing at least a carbon-containing gas into the chamber to generate plasma and forming a protective film at least on the mask film, and (a-b) supplying a processing gas containing at least a noble gas into the chamber to generate plasma and supplying a bias signal to the substrate support unit to etch at least a portion of the protective film and the etching film.

In an embodiment, the etching film is a silicon oxide film or a silicon nitride film.

In an embodiment, the dielectric film is a silicon nitride film or a silicon oxide film.

In an embodiment, the noble gas is argon (Ar) gas.

In an embodiment, in (c), the cycle including (c-a) and (c-b) is repeated a plurality of times, and an increment of the effective value of power or the absolute value of DC voltage of the bias signal in (b) is equal to an increment of the effective value of power or the absolute value of DC voltage of the bias signal in (c).

In an embodiment, in (c), the cycle including (c-a) and (c-b) is repeated a plurality of times, and an increment of the effective value of power or the absolute value of DC voltage of the bias signal in (b) is different from an increment of the effective value of power or the absolute value of DC voltage of the bias signal in (c).

In an embodiment, the increment in (c) is equal to or greater than zero.

In an embodiment, in (c), the cycle including (c-a) and (c-b) is repeated a plurality of times, and, in (c), an effective value of power or an absolute value of DC voltage of the bias signal supplied to the substrate support unit in an (N+1)^{th} cycle (N is an integer of 1 or more) in (c-b) is smaller than an effective value of power or an absolute value of DC voltage of the bias signal supplied to the substrate support unit in an N^{th} cycle in (c-b).

In an embodiment, a number of times the cycle is repeated in (b) is less than a number of times the cycle is repeated in (c).

In an embodiment, in (b-a) and (b-b), the plasma is generated using a source RF signal, and an effective value of power of the source RF signal in (b-a) is greater than an effective value of power of the source RF signal in (b-b).

In an embodiment, each cycle in (b) includes an offset period between (b-a) and (b-b), and the source RF signal and the bias signal are continuously supplied during a period in which (b-a) is executed, the offset period, and a period in which (b-b) is executed.

In an embodiment, an effective value of power of the source RF signal during the offset period is smaller than an effective value of power of the source RF signal in (b-a), and an effective value of power or an absolute value of DC voltage of the bias signal during the offset period is smaller than an effective value of power or an absolute value of DC voltage of the bias signal in (b-b).

In an embodiment, an etching rate (b-b) is higher than an etching rate of the dielectric film.

In an embodiment, an effective value of power or an absolute value of DC voltage of the bias signal in (b-b) continuously increases.

In an embodiment, an effective value of power or an absolute value of DC voltage of the bias signal in (b-b) continuously decreases.

In an embodiment, a plasma processing apparatus includes: a chamber; a substrate support unit disposed within the chamber; and a control unit configured to: (a) prepare a substrate including an etching film and a dielectric film on the substrate support unit, the substrate having a first region where the etching film is exposed and a second region surrounding the first region, and the dielectric film being disposed in the second region; (b) etch the etching film by repeatedly executing, a plurality of times, a cycle including: (b-a) supplying a processing gas containing at least a carbon-containing gas into the chamber to generate a plasma and forming a protective film at least on the dielectric film, and (b-b) supplying a processing gas containing at least a noble gas into the chamber to generate a plasma and supplying a bias signal to the substrate support unit to etch at least a portion of the protective film and the etching film; (c) etch the etching film by executing, one or more times, a cycle including: (c-a) supplying a processing gas containing at least a carbon-containing gas into the chamber to generate a plasma and forming a protective film at least on the dielectric film, and (c-b) supplying a processing gas containing at least a noble gas into the chamber to generate a plasma and supplying a bias signal to the substrate support unit to etch at least a portion of the protective film and the etching film. In (b), an effective value of power or an absolute value of DC voltage of the bias signal supplied to the substrate support unit in an (N+1)^{th} cycle (N is an integer of 1 or more) in (b-b) is greater than an effective value of power or an absolute value of DC voltage of the bias signal supplied to the substrate support unit in an N^{th} cycle in (b-b), and wherein an effective value of power or an absolute value of DC voltage of the bias signal supplied to the substrate support unit in (c-b) is equal to or greater than an effective value of power or an absolute value of DC voltage of the bias signal in (b-b).

Hereinbelow, each embodiment of the present disclosure will be described in detail with reference to the drawings. In each drawing, the same or similar elements will be denoted by the same reference numerals, and redundant descriptions will be omitted. Unless otherwise specified, positional relationships, such as upper, lower, left, and right, will be described based on the positional relationships illustrated in the drawings. The dimensional ratios in the drawings do not indicate the actual ratios, and the actual ratios are not limited to those illustrated in the drawings.

### Configuration Example of Plasma Processing System

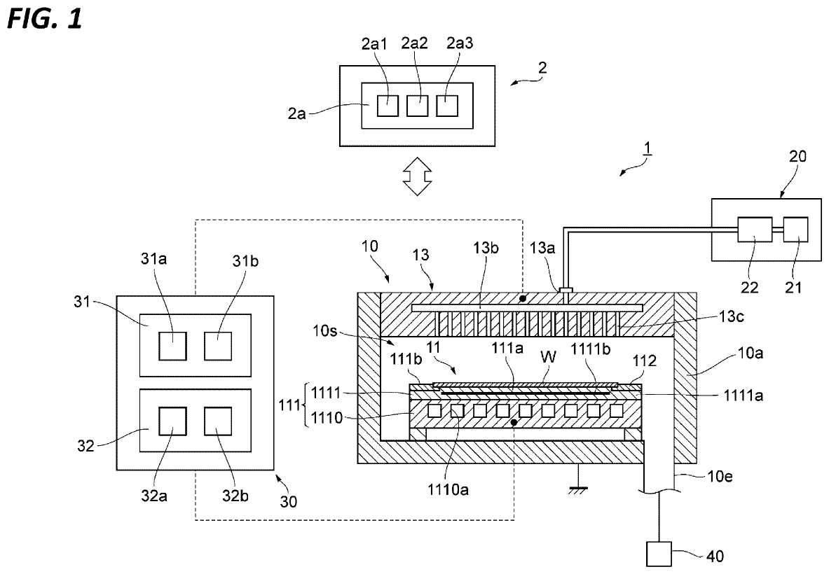

Hereinbelow, a configuration example of a plasma processing system will be described. FIG. 1 is a view illustrating a configuration example of a capacitively-coupled plasma processing apparatus.

A plasma processing system includes a capacitively-coupled plasma processing apparatus 1 and a control unit 2. The capacitively-coupled plasma processing apparatus 1 includes a plasma processing chamber 10, a gas supply unit 20, a power supply 30, and an exhaust system 40. In addition, the plasma processing apparatus 1 includes a substrate support unit 11 and a gas introduction unit. The gas introduction unit is configured to introduce at least one processing gas into the plasma processing chamber 10. The gas introduction unit includes a showerhead 13. The substrate support unit 11 is disposed in the plasma processing chamber 10. The showerhead 13 is disposed above the substrate support unit 11. In an embodiment, the showerhead 13 constitutes at least a portion of the ceiling of the plasma processing chamber 10. The plasma processing chamber 10 has a plasma processing space 10s defined by the showerhead 13, the side wall 10a of the plasma processing chamber 10, and the substrate support unit 11. In addition, the plasma processing chamber 10 includes at least one gas supply port that supplies at least one processing gas to the plasma processing space 10s, and at least one gas discharge port configured to discharge gas from the plasma processing space. The plasma processing chamber 10 is grounded. The showerhead 13 and the substrate support unit 11 are electrically insulated from the housing of the plasma processing chamber 10.

The substrate support unit 11 includes a main body 111 and a ring assembly 112. The main body 111 includes a central region 111a configured to support a substrate W and an annular region 111b configured to support the ring assembly 112. A wafer is an example of the substrate W. The annular region 111b of the main body 111 surrounds the central region 111a of the main body 111 in a plan view. The substrate W is placed on the central region 111a of the main body 111, and the ring assembly 112 is disposed on the annular region 111b of the main body 111 to surround the substrate W on the central region 111a of the main body 111. Accordingly, the central region 111a is also referred to as a “substrate support surface” that supports the substrate W, and the annular region 111b is also referred to as a “ring support surface” that supports the ring assembly 112.

In an embodiment, the main body 111 includes a base 1110 and an electrostatic chuck 1111. The base 1110 includes a conductive member. The conductive member of the base 1110 may serve as a lower electrode. The electrostatic chuck 1111 is disposed on the base 1110. The electrostatic chuck 1111 includes a ceramic member 1111a and an electrostatic electrode 1111b disposed inside the ceramic member 1111a. The ceramic member 1111a has a central region 111a. In an embodiment, the ceramic member 1111a also has an annular region 111b. Other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled to a radio frequency (RF) power supply 31 and/or a direct current (DC) power supply 32, which will be described below, may be disposed inside the ceramic member 1111a. In this case, the at least one RF/DC electrode functions as a lower electrode. When a bias RF signal and/or a DC signal, which will be described below, is supplied to the at least one RF/DC electrode, the RF/DC electrode is also referred to as a “bias electrode.” In addition, the conductive member of the base 1110 and the at least one RF/DC electrode may function as a plurality of lower electrodes. Furthermore, the electrostatic electrode 1111b may function as a lower electrode. Accordingly, the substrate support unit 11 includes at least one lower electrode.

The ring assembly 112 includes one or more annular members. In an embodiment, the one or more annular members include one or more edge rings and at least one cover ring. The edge rings are made of a conductive material or an insulating material, and the cover ring is made of an insulating material.

In addition, the substrate support unit 11 may include a temperature regulating module configured to regulate at least one of the electrostatic chuck 1111, the ring assembly 112, and the substrate to a target temperature. The temperature regulating module may include a heater, a heat transfer medium, a flow path 1110a, or a combination thereof. A heat transfer fluid, such as brine or gas, flows through the flow path 1110a. In an embodiment, the flow path 1110a is formed inside the base 1110, and one or more heaters are disposed inside the ceramic member 1111a of electrostatic chuck 1111. In addition, the substrate support unit 11 may include a heat transfer gas supply unit that supplies a heat transfer gas to the gap between the rear surface of the substrate W and the central region 111a.

The showerhead 13 is configured to introduce at least one processing gas from the gas supply unit 20 into the plasma processing space 10s. The showerhead 13 includes at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. In addition, the showerhead 13 includes at least one upper electrode. In addition to the showerhead 13, the gas introduction unit may include one or more side gas injectors (SGIs) installed in one or more openings formed in the side wall 10a.

The gas supply unit 20 may include one or more gas sources 21 and one or more flow rate controllers 22. In an embodiment, the gas supply unit 20 is configured to supply at least one processing gas from a corresponding one of the gas sources 21 to the showerhead 13 via a corresponding one of the flow rate controllers 22. Each flow rate controller 22 may include, for example, a mass flow controller or a pressure-controlled flow rate controller. In addition, the gas supply unit 20 may include one or more flow rate modulation devices configured to modulate or pulse the flow rate of at least one processing gas.

The power supply 30 includes an RF power supply 31 coupled to the plasma processing chamber 10 via at least one impedance matching circuit. The RF power supply 31 is configured to supply at least one RF signal (RF power) to the at least one lower electrode and/or the at least one upper electrode. As a result, plasma is formed from the at least one processing gas supplied into the plasma processing space 10s. Therefore, the RF power supply 31 may function as at least a portion of a plasma generation unit configured to generate plasma from one or more processing gases in the plasma processing chamber 10. In addition, by supplying a bias RF signal to the at least one lower electrode, a bias potential may be generated in the substrate W, and an ionic component in the formed plasma may be drawn into the substrate W.

In an embodiment, the RF power supply 31 includes a first RF generation unit 31a and a second RF generation unit 31b. The first RF generation unit 31a is coupled to the at least one lower electrode and/or the at least one upper electrode via at least one impedance matching circuit and configured to generate a source RF signal (source RF power) for plasma generation. In an embodiment, the source RF signal has a frequency within the range of 10 MHz to 150 MHz. In an embodiment, the first RF generation unit 31a may be configured to generate a plurality of source RF signals having different frequencies. One or more generated source RF signals are provided to the at least one lower electrode and/or the at least one upper electrode.

The second RF generation unit 31b is coupled to the at least one lower electrode via the at least one impedance matching circuit and is configured to generate a bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency within the range of 100 kHz to 60 MHz. In an embodiment, the second RF generation unit 31a may be configured to generate a plurality of bias RF signals having different frequencies. One or more generated bias RF signals are provided to the at least one lower electrode. In addition, in various embodiments, at least one of the source RF signal and the bias RF signal may be pulsed.

The power supply 30 may include a DC power supply 32 coupled to the plasma processing chamber 10. The DC power supply 32 includes a first DC generation unit 32a and a second DC generation unit 32b. In an embodiment, the first DC generation unit 32a is connected to the at least one lower electrode and configured to generate a first DC signal. The generated first DC signal is applied to the at least one lower electrode. In an embodiment, the second DC generation unit 32b is connected to the at least one upper electrode and configured to generate a second DC signal. The generated second DC signal is applied to the at least one upper electrode.

In various embodiments, at least one of the first and second DC signals may be pulsed. In this case, a sequence of voltage pulses is applied to the at least one lower electrode and/or the at least one upper electrode. The voltage pulses may have a rectangular pulse waveform, a trapezoidal pulse waveform, a triangular pulse waveform, or a combination thereof. In an embodiment, a waveform generation unit configured to generate a sequence of voltage pulses from a DC signal is connected between the first DC generation unit 32a and the at least one lower electrode. Therefore, the first DC generation unit 32a and the waveform generation unit constitute a voltage pulse generation unit. When the second DC generation unit 32b and the waveform generation unit constitute a voltage pulse generation unit, the voltage pulse generation unit is connected to at least one upper electrode. The voltage pulse may have a positive polarity or a negative polarity. In addition, the sequence of voltage pulses may include one or more positive voltage pulses and one or more negative voltage pulses within one cycle. The first and second DC generation units 32a and 32b may be provided in addition to the RF power supply 31, or the first DC generation unit 32a may be provided in place of the second RF generation unit 31b.

The exhaust system 40 may be connected, for example, to a gas discharge port 10e provided at the bottom of the plasma processing chamber 10. The exhaust system 40 may include a pressure regulating valve and a vacuum pump. By the pressure regulating valve, the pressure in the plasma processing space 10s is regulated. The vacuum pump may include a turbo molecular pump, a dry pump, or a combination thereof.

The control unit 2 processes computer-executable commands to enable the plasma processing apparatus 1 to execute various steps described herein. The control unit 2 may be configured to control each element of the plasma processing apparatus 1 to perform various steps described herein. In an embodiment, a part or all of the control unit 2 may be configured as a system outside the plasma processing apparatus 1. The control unit 2 may include a processor 2a1, a storage 2a2, and a communication interface 2a3. The control unit 2 is implemented by, for example, a computer 2a. The processor 2al may be configured to perform various control operations by reading a program from the storage 2a2 and executing the read program. This program may be stored in the storage 2a2 in advance, or may be acquired via a medium when necessary. The acquired program is stored in the storage 2a2, and is read from the storage 2a2 and executed by the processor 2a1. The medium may be various storage media readable by the computer 2a, or may be a communication line connected to the communication interface 2a3. The processor 2a1 may be a central processing unit (CPU). The storage 2a2 may include random access memory (RAM), read only memory (ROM), hard disk drive (HDD), solid state drive (SSD), or a combination thereof. The communication interface 2a3 may communicate with the plasma processing apparatus 1 via a communication line such as a local area network (LAN).

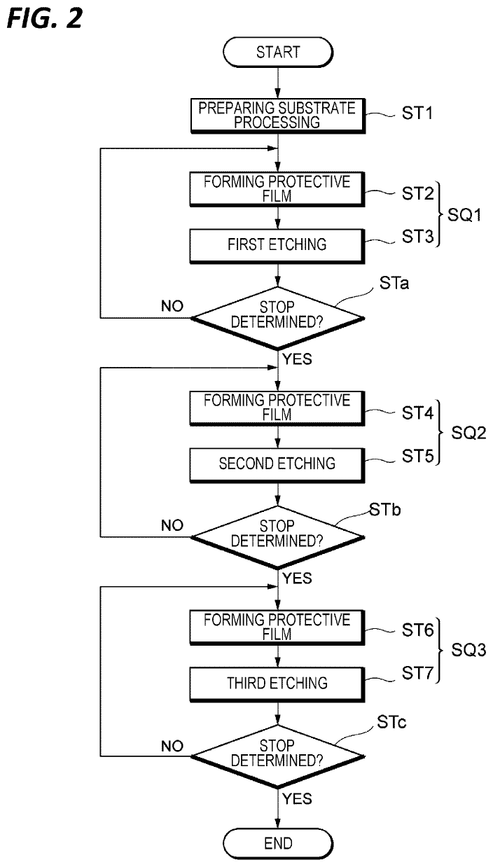

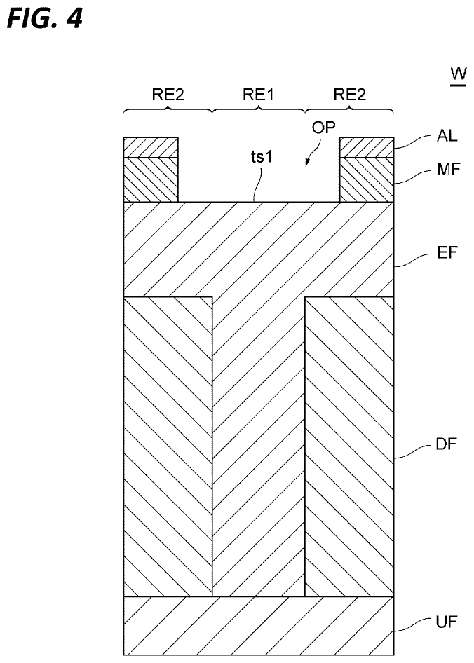

FIG. 2 is a flowchart illustrating a plasma processing method according to an embodiment (hereinafter referred to as “the present processing method”). As illustrated in FIG. 2, the present processing method includes: a substrate processing preparation step ST1, a first sequence SQ1 (a protective film formation step ST2 and a first etching step ST3), a stop determination step STa, a second sequence SQ2 (a protective film formation step ST4 and a second etching step ST5), a stop determination step STb, a third sequence SQ3 (a protective film formation step ST6 and a third etching step ST7), and a stop determination step STc. The processing in each step may be executed using the plasma processing system illustrated in FIG. 1. The present processing method may include two or more sequences. As an example, the number of sequences may be five or more, or ten or more. In addition, the substrate processing preparation step ST1 may include a step of placing a substrate W on a substrate support unit 11 and a step initially processing of the substrate W. As an example, the initial processing may include etching a portion of an etching film EF (see FIG. 4).

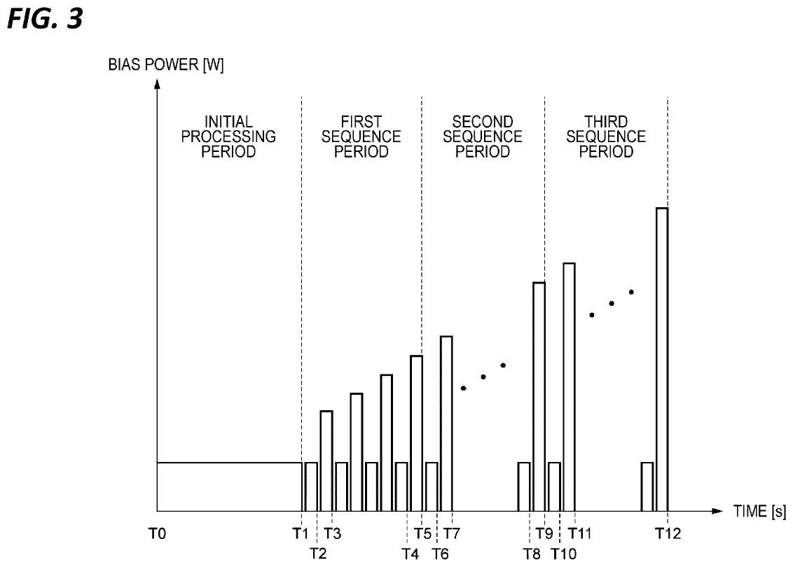

FIG. 3 is a timing chart illustrating changes in bias power in the present processing method. In FIG. 3, the horizontal axis represents time, and the vertical axis represents bias power. When the bias signal is an RF signal, the bias power represents the effective value of power of the bias signal. The effective value of power of the bias signal may also be referred to as “bias power” or “power.” The bias signal may also be a pulse of a negative polarity DC voltage.

In the timing chart illustrated in FIG. 3, after a substrate W is placed on the substrate support unit 11, the initial processing in step ST1 is executed during time period T0 to T1, the first sequence SQ1 is executed during time period T1 to T5, the second sequence SQ2 is executed during time period T5 to T9, and the third sequence SQ3 is executed during time period T9 to T12.

Below, an example is described where the control unit 2 controls each component of the plasma processing apparatus 1 to execute processing on the substrate W in each step included in the present processing method.

### (Step ST1: Providing Substrate)

In step ST1, the substrate W is provided in the plasma processing space 10s of the plasma processing apparatus 1. In step ST1, the substrate W is first placed in a central area 111a of the substrate support unit 11.

FIG. 4 is a view illustrating an example of the cross-sectional structure of the substrate W placed on the substrate support unit 11. The substrate W includes an underlying film UF, a dielectric film DF, an etching film EF, a mask film MF, and an antireflection film AL. The substrate W may be used in the manufacture of semiconductor devices. The semiconductor devices include, for example, semiconductor memory devices such as DRAM and 3D-NAND flash memory. In addition, the structure of the substrate W illustrated in FIG. 4 may be a structure for forming a self-aligned contact (SAC) in a first region RE1.

The underlying film UF may be, for example, a silicon wafer or an organic film, a metal film, or a semiconductor film formed on a silicon wafer. The underlying film UF may be formed by laminating multiple films.

The dielectric film DF may be, for example, a silicon nitride film, a silicon oxide film, or a boron nitride film. As illustrated in FIG. 4, the dielectric film DF is disposed in a second region RE2 on the substrate W. In addition, in the first region RE1 surrounded by the second region RE2, the dielectric film DF is disposed to define a recess on the underlying film UF.

The etching film EF is the target film for etching in the present processing method. The etching film EF may be a silicon-containing film. The silicon-containing film may include a silicon oxide film or a silicon nitride film. As illustrated in FIG. 4, the etching film EF may be disposed in the first region RE1 and the second region RE2. In an example, a portion of the etching film EF may be disposed on the dielectric film DF in the second region RE2. In addition, another portion of the etching film EF may be disposed on the underlying film UF in the first region RE1. The etching film EF has a top surface ts1. The top surface ts1 of the etching film EF is partially exposed in portions of the first region RE1 and the second region RE2. The etching film EF may be a multilayer film including two or more layers.

The mask film MF is a film that functions as a mask during the etching of the etching film EF. As illustrated in FIG. 4, the mask film MF is disposed on the etching film EF such that the top surface ts1 of the etching film EF is partially exposed. The mask film MF may include an opening pattern that exposes the etching film EF in portions of the first and second regions RE1 and RE2. In an example, the mask film MF may be a boron-containing silicon film, a carbon-containing film, or a tungsten silicon film.

The antireflection film AL is a film provided on the mask film MF to prevent reflection. The antireflection film AL may be a titanium-containing film, such as a TiN film or a TiW film. The antireflection film AL may have the same opening pattern as the mask film MF. In addition, the antireflection film AL may be included in the mask film MF.

In addition, step ST1 may include a step of initially processing the substrate W after placing the substrate W on the substrate support unit 11, as illustrated in FIG. 4. In an example, during the initial processing period (time T0 to T1) illustrated in FIG. 3, the etching film EF illustrated in FIG. 4 may be etched as the initial processing. The etching film EF may be etched by plasma generated from the processing gas supplied into the plasma processing chamber 10.

The processing gas may contain, for example, a fluorine-containing gas or a chlorine-containing gas. During the initial processing period, the processing gas may be supplied into the plasma processing chamber 10 at a constant flow rate. In an example, a source RF signal is supplied to the lower electrode of the substrate support unit 11, generating a plasma from the processing gas. In addition, a bias RF signal may be supplied to the lower electrode (bias electrode) of the substrate support unit 11. As illustrated in FIG. 3, the bias power of the bias RF signal may remain constant during the initial processing period.

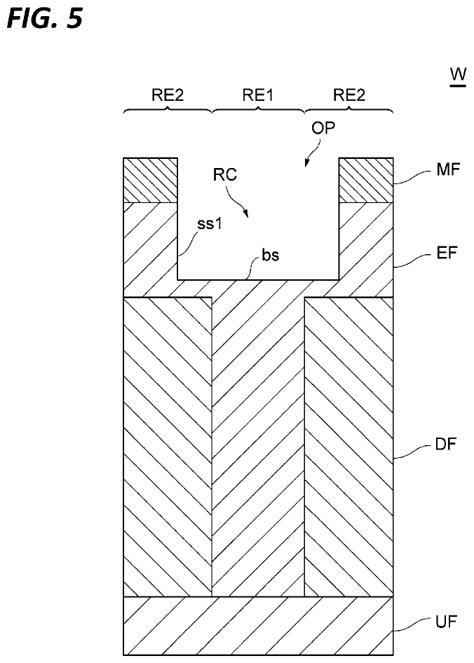

FIG. 5 is a view illustrating an example of a cross-section of the substrate W after executing step ST1. In step ST1, when the substrate W is etched, portions of the etching film EF disposed in the first and second regions RE1 and RE2 are etched, and a recess RC is formed in the etching film EF, as illustrated in FIG. 5. The recess RC is a space enclosed by the side surface ss1 and the bottom surface bs of the etching film EF. In step ST1, the etching film EF may be etched such that the dielectric film DF is not exposed, or the etching film EF may be etched such that a portion of the dielectric film DF is exposed.

### (Execution of First Sequence SQ1)

The first sequence SQ1 includes a protective film formation step (step ST2) and a first etching step (step ST3). In the first sequence SQ1, during the first sequence period illustrated in FIG. 3, a cycle that includes steps ST2 and ST3 is executed multiple times. That is, in the first sequence SQ1, steps ST2 and ST3 are alternately executed. FIG. 3 illustrates an example in which the cycle is executed four times. The number of times the cycle is executed in the first sequence SQ1 is not limited to this and may be arbitrarily set. The first sequence SQ1 may be initiated while the dielectric film DF is not exposed, as illustrated in FIG. 5.

In addition, as illustrated in FIG. 3, in the first sequence SQ1, the bias power may be low in the protective film formation step ST2 and high in the first etching step ST3. Moreover, in the first sequence SQ1, the bias power in step ST2 may remain constant. Meanwhile, as illustrated in FIG. 3, the bias power supplied in step ST3 increases as the cycle progresses. During the first sequence period, the bias power in step ST3 may increase by a fixed increment each time the process transitions from one cycle to the next cycle. That is, during the first sequence period, the bias power in step ST3 may increase linearly. In addition, during the first sequence period, the bias power in step ST3 of a certain cycle ((N+1)^{th} cycle, where N is an integer of 1 or more) may be greater than the bias power in step ST3 of the immediately preceding cycle (N^{th} cycle). The increment of bias power between consecutive cycles may be variable rather than fixed. During the second sequence period, the bias power may remain constant in some cycles.

### (Step ST2: Formation of Protective Film)

In step ST2 (e.g., from time T1 to T2 in FIG. 3), a protective film PF is formed on the substrate W. The protective film PF is formed by the plasma generated from the processing gas supplied into the plasma processing chamber 10. That is, in step ST2, the processing gas is first supplied from the gas supply unit 20 into the plasma processing space 10s. Then, a source RF signal is supplied to the lower electrode of the substrate support unit 11. In addition, a bias RF signal is supplied to the lower electrode (bias electrode) of the substrate support unit 11. The protective film PF is deposited on the substrate W by the plasma generated from the processing gas.

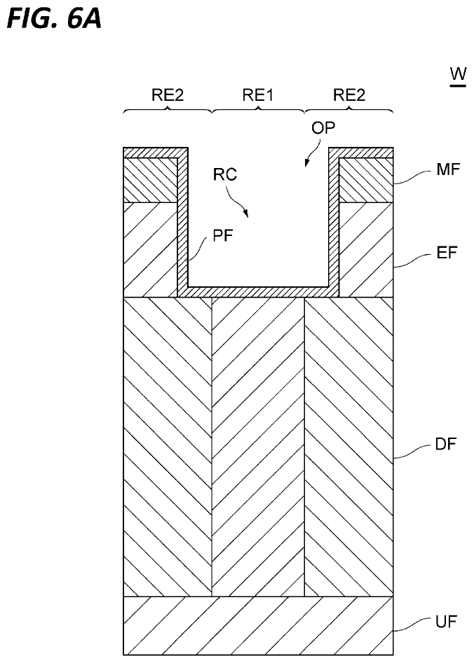

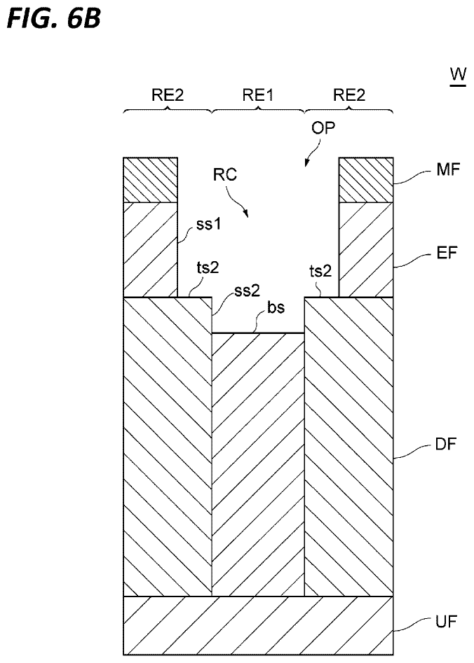

FIG. 6A is a view illustrating an example of the cross-sectional structure of the substrate W after executing step ST2. As illustrated in FIG. 6A, the protective film PF may be formed on the top and side surfaces of the mask film MF, as well as on the side surface ss1 and bottom surface bs of the etching film EF that define the recess RC. At the initiation of the first sequence SQ1, the dielectric film DF may or may not be exposed. In the case where the dielectric film DF is not exposed, when the etching film EF is etched by repeating steps ST2 and ST3 in the first sequence SQ1, the protective film PF may be formed on the dielectric film DF upon exposure of a portion of the dielectric film DF, as illustrated in FIG. 6A.

In step ST2, active species in the plasma generated from the processing gas may be adsorbed onto the substrate W to be deposited as the protective film PF. The thickness of the protective film PF formed in step ST2 may be on the order of several atomic layers. In addition, the deposition rate of the protective film PF on the dielectric film DF may be faster than the deposition rate of the protective film PF on the etching film EF. That is, the thickness of the protective film PF formed on the dielectric film DF may be greater than the thickness of the protective film PF formed on the etching film EF.

In step ST2, the processing gas contains a carbon-containing gas. A deposit generated from the carbon-containing gas by the plasma may be deposited on the substrate W to form the protective film PF. The carbon-containing gas may be represented by CₐF_{b} gas (where a and b are integers of 1 or more) or C_{c}H_{d}Fₑ gas (where c, d, and e are integers of 1 or more). For example, at least one selected from the group consisting of CF₄ gas, C₂F₆ gas, C₂F₄ gas, C₃F₈ gas, C₄F₈ gas, CH₂F₂ gas, C₃H₂F₄ gas, C₃H₂F₆ gas, C₃H₃F₅ gas, C₄H₂F₆ gas, C₄H₅F₅ gas, C₄H₂F₈ gas, C₅H₂F₆ gas, C₅H₂F₁₀ gas, and C₅H₃F₇ gas may be used as the carbon-containing gas. The flow rate of the carbon-containing gas in the processing gas may be appropriately controlled. By controlling the flow rate of the carbon-containing gas, the deposition rate of the protective film PF may be controlled.

In step ST2, the processing gas may further contain an oxygen-containing gas. By including the oxygen-containing gas in the processing gas, both the formation of the protective film PF by the carbon-containing gas and the etching of the protective film PF by the oxygen-containing gas may occur. By adjusting the flow rate ratio between the carbon-containing gas and the oxygen-containing gas in the processing gas, the deposition rate and/or the deposition amount of the protective film PF may be adjusted.

### (Step ST3: First Etching)

In step ST3 (e.g., from time T2 to T3 in FIG. 3), the protective film PF and the etching film EF are etched. The etching film EF is etched by the plasma generated from the processing gas supplied into the plasma processing chamber 10. That is, in step ST3, the processing gas is first supplied from the gas supply unit 20 into the plasma processing space 10s. In addition, a source RF signal is supplied to the lower electrode of the substrate support unit 11, thereby generating a plasma from the processing gas. In addition, a bias RF signal is supplied to the lower electrode (bias electrode) of the substrate support unit 11. As a result, the protective film PF is etched. Once the protective film PF is etched and the etching film EF is exposed, the etching film EF is etched in the first region RE1.

The processing gas contains a noble gas. The protective film PF and the etching film EF may be etched by the active species generated from the noble gas by the plasma. The noble gas may be, for example, Ar gas. The flow rate of the noble gas in the processing gas may be appropriately set or adjusted. The etching rate of the protective film PF and the etching film EF may be controlled based on the flow rate of the noble gas in the processing gas.

The processing gas in step ST3 may further contain a carbon-containing gas. By containing the carbon-containing gas in the processing gas, both the etching of the protective film PF by the noble gas and the formation of the protective film PF by the carbon-containing gas may occur in step ST3. Thus, the etching rate and/or deposition rate of the protective film PF may be adjusted by adjusting the flow rate ratio between the noble gas and the carbon-containing gas in the processing gas.

The etching rate of the protective film PF on the etching film EF may be faster than the etching rate of the protective film PF on the dielectric film DF. In addition, as described above, the thickness of the protective film PF formed on the dielectric film DF may be greater than that of the protective film PF formed on the etching film EF. Accordingly, in step ST3, the etching film EF may be exposed while the protective film PF remains on the dielectric film DF. Accordingly, in step ST3, the etching film EF may be etched while the dielectric film DF remains protected by the protective film PF. The thickness of the protective film PF and/or the etching film EF etched in step ST3 may be on the order of several atomic layers.

FIG. 6B is a view illustrating an example of the cross-sectional structure of the substrate W after executing step ST3. As illustrated in FIG. 6B, the protective film PF is removed at least in the first region RE1, and the etching film EF is etched in the first region RE1. As a result, a recess RC is formed in the first region RE1. The recess RC is a space enclosed by the top surface ts2 and the side surface ss2 of the dielectric film DF, as well as the side surface ss1 and the bottom surface bs (the top surface of the etching film EF in the first region RE1) of the etching film EF.

### (Step STa: Stop Determination)

In step STa, it is determined whether a stop condition is satisfied. The stop condition is the number of times the cycle including steps ST2 and ST3 is executed. That is, in step STa, it is determined whether the number of times the cycle has been executed in the first sequence SQ1 has reached a predetermined number. For example, when the number of times the cycle has been executed in the first sequence SQ1 has reached the preset number, the first sequence SQ1 is terminated. When the number of times the cycle has been executed in the first sequence SQ1 has not yet reached the preset number, the process returns to step ST2, and a new cycle is executed. The number of times the cycle is executed in the first sequence SQ1 may be set based on the thickness of the etching film EF (i.e., the depth of the recess RC to be formed). By repeating steps ST2 and ST3 in the first sequence SQ1, the etching film EF may be further etched in the first region RE1, as illustrated in FIG. 6B.

### (Execution of Second Sequence SQ2)

The second sequence SQ2 includes a protective film formation step (step ST4) and a second etching step (step ST5). In the second sequence SQ2, during the second sequence period illustrated in FIG. 3, a cycle including steps ST4 and ST5 is executed multiple times. That is, in the second sequence SQ2, steps ST4 and ST5 are alternately executed.

In addition, as illustrated in FIG. 3, in the second sequence SQ2, the bias power may be low in the protective film formation step ST4 and high in the second etching step ST5. Moreover, in the second sequence SQ2, the bias power in step ST4 may remain constant. Meanwhile, as illustrated in FIG. 3, the bias power supplied in step ST5 increases as the cycle progresses. During the second sequence period, the bias power in step ST5 may increase by a fixed increment each time the process transitions from one cycle to the next cycle. That is, during the second sequence period, the bias power in step ST5 may increase linearly. In addition, during the second sequence period, the bias power in step ST5 of a certain cycle ((N+1)^{th} cycle) may be greater than the bias power in step ST5 of the immediately preceding cycle (N^{th} cycle). The increment of bias power between consecutive cycles may vary rather than remain fixed. During the second sequence period, the bias power may remain constant in some cycles In addition, the magnitude of the bias power may be determined based on the depth of the recess RC. Furthermore, the bias power in step ST5 of the first cycle of the second sequence SQ2 (from time T6 to T7) may be greater than the bias power in step ST3 of the final cycle of the first sequence SQ1 (from time T4 to T5).

### (Step ST4: Formation of Protective Film)

In step ST4 (e.g., from time T5 to T6 in FIG. 3), a protective film PF is formed on the substrate W. The protective film PF is formed by the plasma generated from the processing gas supplied into the plasma processing chamber 10. In step ST4, the protective film PF may be formed in the same manner as described in step ST2.

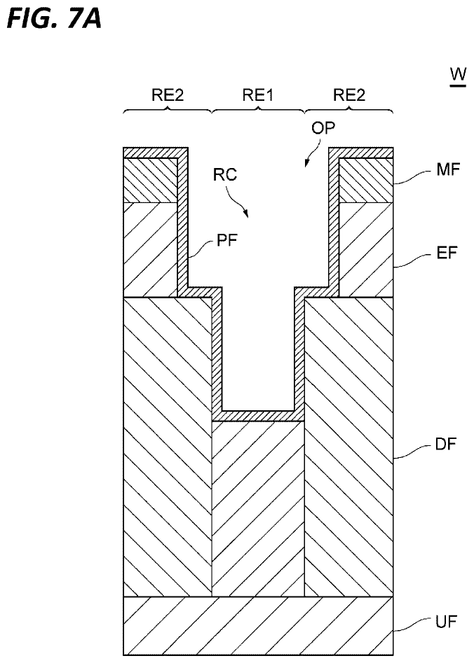

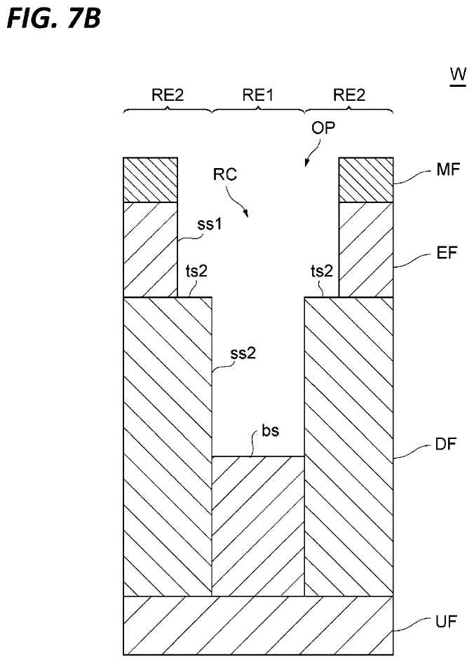

FIG. 7A is a view illustrating an example of the cross-sectional structure of the substrate W after execution of step ST4. As illustrated in FIG. 7A, the protective film PF is formed on the substrate W. As illustrated in FIG. 7A, the protective film PF may be formed on the top and side surfaces of the mask film MF, on each surface of the etching film EF defining the recess RC, and on the top and side surfaces of the dielectric film DF.

In step ST4, the processing gas contains a carbon-containing gas. Activated species generated from the carbon-containing gas by the plasma may be adsorbed onto the substrate W to form the protective film PF. The processing gas used in the second sequence SQ2 may contain the same carbon-containing gas as the processing gas used in the first sequence SQ1 or may contain a different carbon-containing gas.

### (Step ST5: Second Etching)

In step ST5 (e.g., from time T6 to T7 in FIG. 3), the protective film PF and the etching film EF are etched. The etching film EF is etched by the plasma generated from the processing gas supplied into the plasma processing chamber 10. In step ST5, the protective film PF and the etching film EF may be etched in the same manner as described in step ST3.

The processing gas contains a noble gas. The protective film PF and the etching film EF in the first region RE1 may be etched by activated species generated from the noble gas by the plasma. The processing gas used in the second sequence SQ2 may contain the same noble gas as the processing gas used in the first sequence SQ1 or may contain a different noble gas.

FIG. 7B is a view illustrating an example of the cross-sectional structure of the substrate W after execution of step ST5. As illustrated in FIG. 7B, the protective film PF is removed at least in the first region RE1, and the etching film EF is further etched in the first region RE1. That is, the recess RC is further deepened in the first region RE1.

### (Step STb: Stop Determination)

In step STb, it is determined whether a stop condition is satisfied. The stop condition is the number of times the cycle including steps ST4 and ST5 is executed. That is, in step STb, it is determined whether the number of times the cycle has been executed in the second sequence SQ2 has reached a predetermined number. For example, when the number of times the cycle has been executed in the second sequence SQ2 reaches a preset number, the second sequence SQ2 is terminated. When the number of times the cycle has been executed in the second sequence SQ2 has not reached the preset number, the process returns to step ST4, and a new cycle is executed. The number of times the cycle is executed in the second sequence SQ2 may be set based on the thickness of the etching film EF (i.e., the depth of the recess RC to be formed). By repeating steps ST4 and ST5 in the second sequence SQ2, the etching film EF in the first region RE1 is further etched, as illustrated in FIG. 7B.

### (Execution of Third Sequence SQ3)

The third sequence SQ3 includes a protective film formation step (step ST6) and a third etching step (step ST7). In the third sequence SQ3, during the third sequence period illustrated in FIG. 3, a cycle including steps ST6 and ST7 is executed multiple times. That is, in the third sequence SQ3, steps ST6 and ST7 are alternately executed.

As illustrated in FIG. 3, in the third sequence SQ3, the bias power may be low in the protective film formation step ST6 and high in the third etching step ST7. Moreover, in the third sequence SQ3, the bias power in step ST6 may remain constant. Meanwhile, as illustrated in FIG. 3, the bias power supplied in step ST7 increases as the cycle progresses. During the third sequence period, the bias power in step ST7 may increase by a fixed increment each time the process transitions from one cycle to the next cycle. That is, during the third sequence period, the bias power in step ST7 may increase linearly. In addition, during the third sequence period, the bias power in step ST7 of a certain cycle ((N+1)^{th} cycle) may be greater than the bias power in step ST7 of the immediately preceding cycle (N^{th} cycle). The increment of bias power between consecutive cycles may vary rather than remain fixed. During the third sequence period, the bias power may remain constant in some cycles In addition, the magnitude of the bias power may be determined based on the depth of the recess RC. Furthermore, the bias power in step ST7 of the first cycle of the third sequence SQ3 (from time T10 to T11) may be greater than the bias power in step ST5 of the final cycle of the second sequence SQ2 (from time T8 to T9).

### (Step ST6: Formation of Protective Film)

In step ST6 (e.g., from time T9 to T10 in FIG. 3), a protective film PF is formed on the substrate W. The protective film PF is formed by the plasma generated from the processing gas supplied into the plasma processing chamber 10. In step ST6, the protective film PF may be formed in the same manner as described in steps ST2 and ST4.

In step ST6, the processing gas contains a carbon-containing gas. Activated species generated from the carbon-containing gas by the plasma may be adsorbed onto the substrate W to form the protective film PF. The processing gas used in the third sequence SQ3 may contain the same carbon-containing gas as the processing gas used in the first and second sequences SQ1 and SQ2 or may contain a different carbon-containing gas.

### (Step ST7: Third Etching)

In step ST7 (e.g., from time T10 to T11 in FIG. 3), the protective film PF and the etching film EF are etched. The etching film EF is etched by the plasma generated from the processing gas supplied into the plasma processing chamber 10. In step ST7, the protective film PF and the etching film EF may be etched in the same manner as described in steps ST3 and ST5.

The processing gas contains a noble gas. The protective film PF and the etching film EF in the first region RE1 may be etched by activated species generated from the noble gas by the plasma. The processing gas used in the third sequence SQ3 may contain the same noble gas as that used in the first and second sequences SQ1 and SQ2 or may contain a different noble gas.

### (Step STc: Stop Determination)

In step STc, it is determined whether a stop condition is satisfied. The stop condition is the number of times the cycle including steps ST6 and ST7 is executed. That is, in step STc, it is determined whether the number of times the cycle has been executed in the third sequence SQ3 has reached a predetermined number. For example, when the number of times the cycle has been executed in the third sequence SQ3 reaches a preset number, the third sequence SQ3 is terminated. When the number of times the cycle has been executed in the third sequence SQ3 has not yet reached the preset number, the process returns to step ST6, and a new cycle is executed. The number of times the cycle is executed in the third sequence SQ3 may be set in consideration of over-etching.

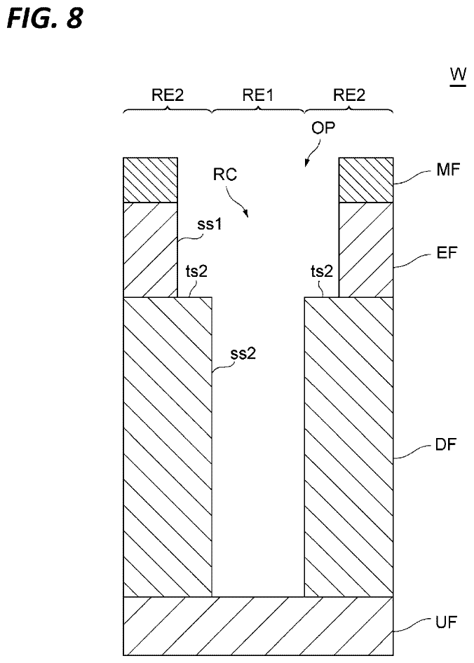

FIG. 8 is a view illustrating an example of the cross-sectional structure of the substrate W after executing the third sequence SQ3. As illustrated in FIG. 8, the underlying film UF in the first region RE1 is exposed on the substrate W.

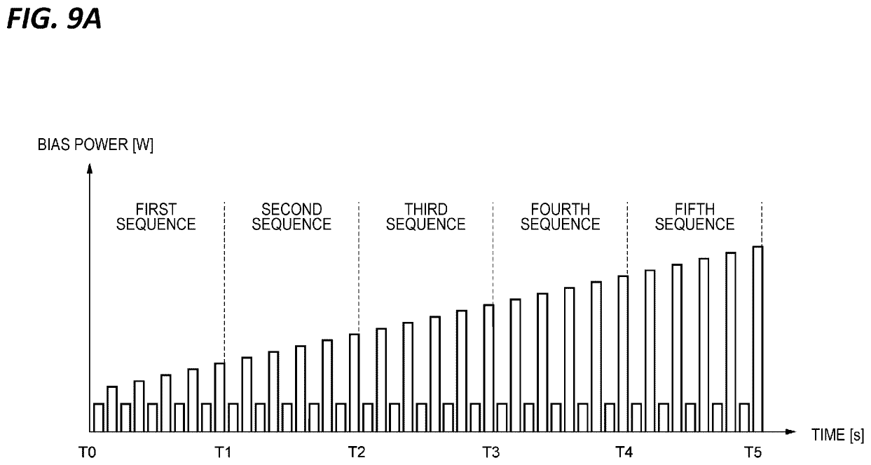

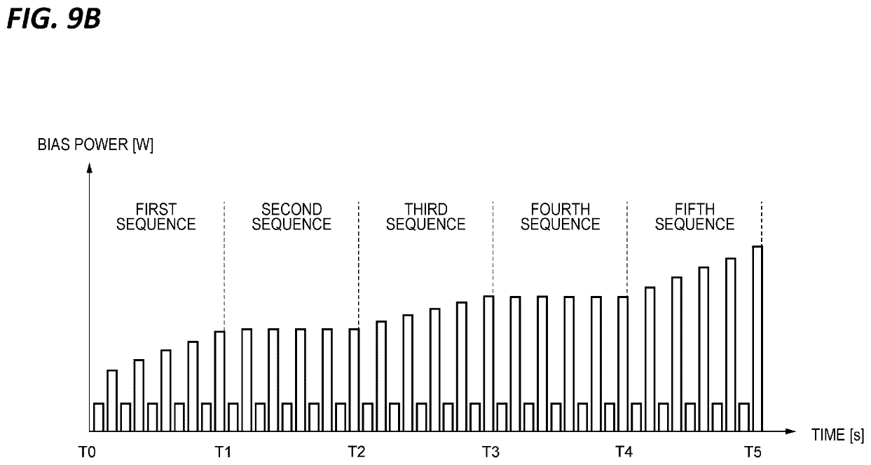

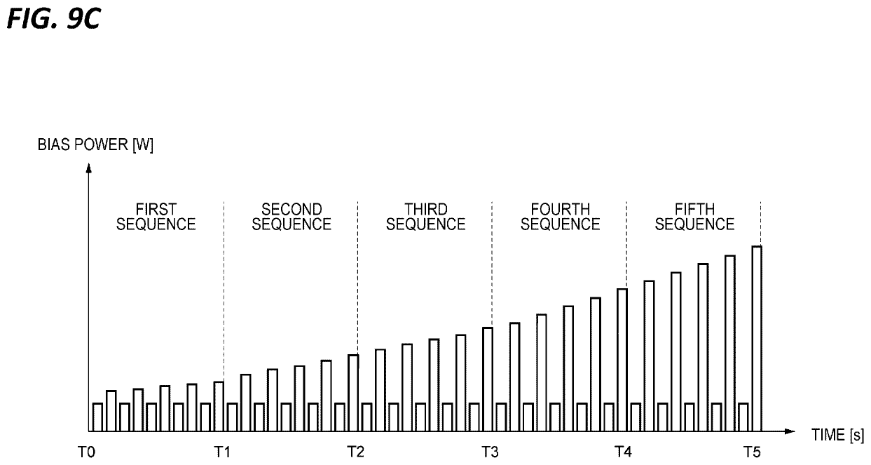

FIGS. 9A, 9B, and 9C are timing charts illustrating an example of the bias power in the present processing method. FIGS. 9A, 9B, and 9C (hereinafter collectively referred to as “FIG. 9”) represent time on the horizontal axis and bias power on the vertical axis. Each example illustrated in FIG. 9 includes five consecutive sequences. FIG. 9A illustrates an example in which a cycle including the deposition step of the protective film PF and the etching step of the etching film EF is executed five times in each sequence.

In the example illustrated in FIG. 9A, the increment of bias power between adjacent etching steps in the first to the fifth sequences remains constant. That is, as illustrated in FIG. 9A, the bias power continuously increases in each sequence.

The example illustrated in FIG. 9B includes both sequences in which the bias power in the etching step increases and sequences in which the bias power in the etching step remains constant. Specifically, in the first, third, and fifth sequences, the bias power increases, while in the second and fourth sequences, the bias power remains constant. The increment of bias power in the first, third, and fifth sequences (the slopes during time periods T0 to T1, T2 to T3, and T4 to T5 in FIG. 7B) is the same. In addition, the increment of bias power between the etching steps in the second and fourth sequences (the slopes during time periods T1 to T2 and T3 to T4 in FIG. 7B) is zero.

In the example illustrated in FIG. 9C, the increment of bias power between etching steps varies in each sequence. That is, in the example illustrated in FIG. 9C, as the cycle progresses in each sequence, the increment of bias power in the etching step increases.

The bias power increase pattern in the present processing method is not limited to the examples illustrated in FIG. 9. In the present processing method, the increment of bias power in the etching step of each sequence may be arbitrarily set, and accordingly, the bias power increase pattern may also be arbitrarily set.

In at least one sequence, the bias power in the etching step may decrease as the cycle progresses. For example, when etching is capable of reaching the underlying film UF during the execution of the final sequence in the present processing method (the fifth sequence in the example illustrated in FIG. 9), the bias power may continuously decrease in some or all of the multiple cycles included in the final sequence. This may reduce damage to the underlying film UF even when etching reaches the underlying film UF during the execution of the final sequence.

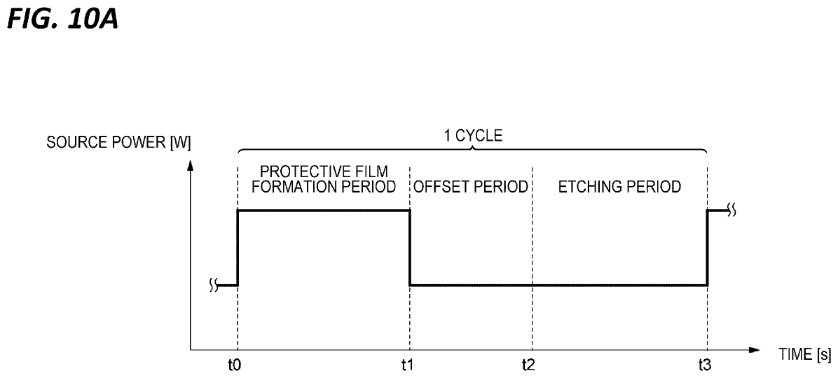

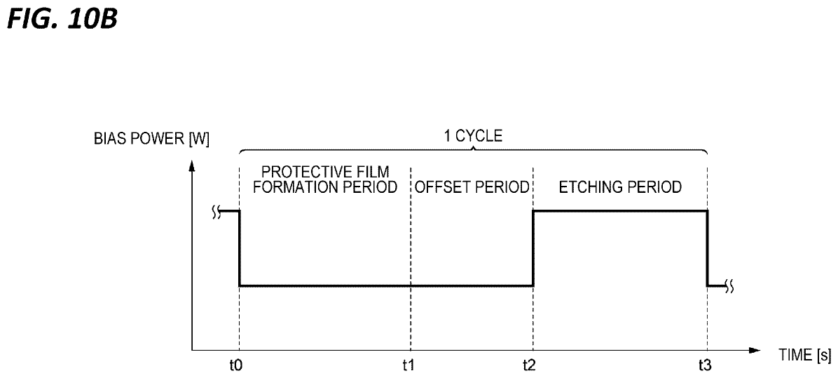

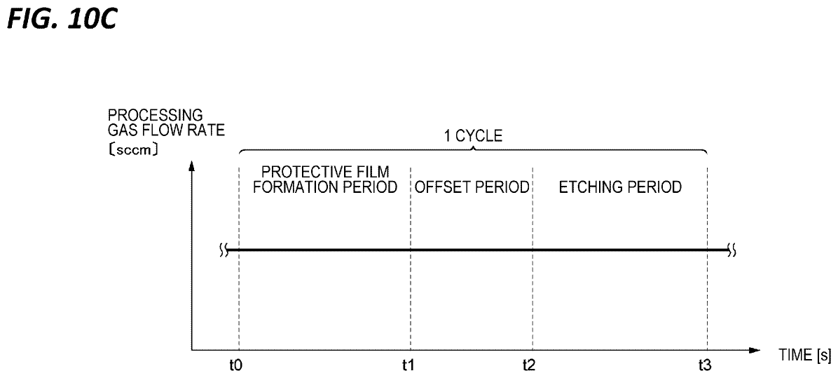

FIGS. 10A, 10B, and 10C are timing charts illustrating the details of the cycles included in each sequence. FIGS. 10A, 10B, and 10C respectively illustrate examples of changes in the power of the source RF signal (also referred to as “source power”), bias power, and processing gas flow rate in each cycle. In FIGS. 10A, 10B, and 10C (hereinafter collectively referred to as “FIG. 10”), the horizontal axes represent time, while the vertical axes represent source power, bias power, and processing gas flow rate, respectively. As illustrated in FIG. 10, a protective film formation step (e.g., step ST2) is executed during the protective film formation period, and an etching step (e.g., step ST3) is executed during the etching period. In addition, as illustrated in FIG. 10, each cycle may include an offset period between the protective film formation period and the etching period.

In the present processing method, the source power may vary between high power and low power. As an example, as illustrated in FIG. 10A, the source power may become a first power during the protective film formation period and may become a second power lower than the first power during the etching period. In addition, the source power may become the second power during the offset period. That is, during the offset period, the source power may become the same second power as in the etching period. The second power may be 0 W.

As another example, as illustrated in FIG. 10B (and FIG. 3), the bias power may become a third power during the protective film formation period and may become a fourth power higher than the third power during the etching period. In addition, during the offset period, the bias power may become the same third power as in the protective film formation period. The third power may be 0 W.

As another example, as illustrated in FIG. 10C, the processing gas flow rate may remain constant throughout the protective film formation period, the offset period, and the etching period. The processing gas flow rate may be the total flow rate, including all gases supplied to the plasma processing chamber 10.

The source power, bias power, and processing gas flow rate may increase or decrease during the protective film formation period t0 to t1 and/or the etching period t2 to t3. The increase or decrease may be a linear increase or decrease. The flow rate of a carbon-containing gas or a noble gas in the processing gas may be increased or decreased during the protective film formation period and/or the etching period. The flow rate may be set based on the amount required to form or etch the protective film PF.

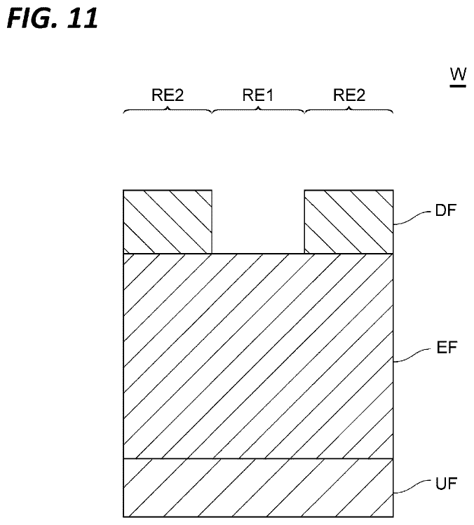

FIG. 11 is a view illustrating another example of the cross-sectional structure of a substrate W to which the present processing method is applicable. FIG. 11 illustrates the cross-sectional structure of a substrate W at the initiation of the first sequence SQ1. In this example, the substrate W has an etching film EF and a dielectric film DF laminated in this order on an underlying film UF. In this example, the etching film EF may be etched using the present processing method in the same manner as in the example described based on the flowchart in FIG. 2. This allows the etching film EF to be etched while protecting the dielectric film DF. Consequently, the etching film EF may be etched while suppressing etching of the dielectric film DF.

In this example, the first region RE1 is a region in which the etching film EF is exposed in a plan view of the substrate W. The second region RE2 is a region in which the dielectric film DF is disposed in a plan view of the substrate W.

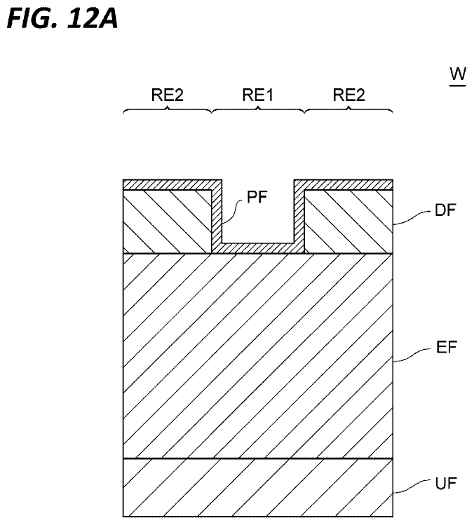

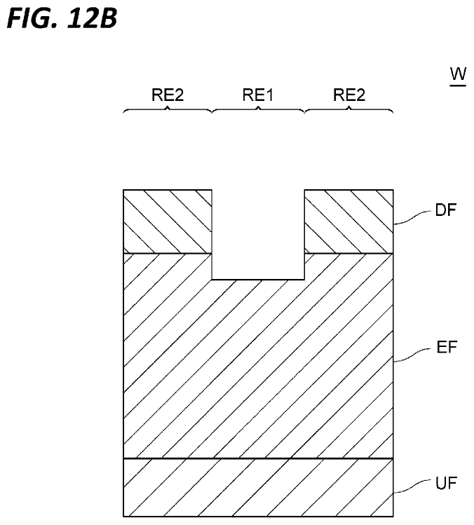

When the present processing method is applied to the substrate W illustrated in FIG. 11, the formation of the protective film illustrated in FIG. 12A and the etching of the protective film PF and the etching film EF illustrated in FIG. 12B are repeated in the same manner as in the example described along the flowchart in FIG. 2. This allows the etching film EF to be etched while suppressing etching of the dielectric film DF.

In each of the above embodiments, the bias signal has been described in terms of bias power, but it may also be DC voltage applied to the substrate support unit. The DC voltage of the bias signal may be negative DC voltage pulses (a sequence of voltage pulses). That is, in the third step of the first sequence SQ1, the fifth step of the second sequence SQ2, and the seventh step of the third sequence SQ3, the absolute value of DC voltage may be increased as the cycle progresses. The absolute value of DC voltage during the offset period of each cycle may be smaller than the absolute value of DC voltage during the etching period.

As illustrated in FIGS. 3, 9A, and 9C, the effective value of the bias signal power or the absolute value of DC voltage may be gradually increased along with the etching depth (or processing time), while controlling other process parameters. Specifically, at least one of the temperature of the substrate support unit 11 and the source power may be gradually increased. In addition, while gradually decreasing the effective value of the bias signal power or the absolute value of DC voltage, other process parameters may also be controlled. Specifically, at least one of the temperature of the substrate support unit 11 and the source power may be gradually decreased.

Each of the above embodiments has been described for illustrative purposes, and various modifications may be made without departing from the scope and spirit of the present disclosure. For example, the present processing method may be executed not only using the capacitively-coupled plasma processing apparatus 1 but also using any plasma processing apparatus employing other plasma sources, such as inductively coupled plasma or microwave plasma.

(Appendix 1) A plasma processing method performed in a plasma processing apparatus including a chamber and a substrate support disposed in the chamber, the plasma processing method comprising:
(a) preparing a substrate including an etching film and a dielectric film on the substrate support, the substrate including a first region where the etching film is exposed and a second region surrounding the first region, and the dielectric film being disposed in the second region;
(b) etching the etching film by repeatedly executing, a plurality of times, a cycle including:
   (b-a) supplying a processing gas containing at least a carbon-containing gas into the chamber to generate a plasma and forming a protective film at least on the dielectric film, and
   (b-b) supplying a processing gas containing at least a noble gas into the chamber to generate a plasma and supplying a bias signal to the substrate support to etch at least a portion of the protective film and the etching film; and
(c) etching the etching film by executing, one or more times, a cycle including:
   (c-a) supplying a processing gas containing at least a carbon-containing gas into the chamber to generate a plasma and forming a protective film at least on the dielectric film, and
   (c-b) supplying a processing gas containing at least a noble gas into the chamber to generate a plasma and supplying a bias signal to the substrate support to etch at least a portion of the protective film and the etching film,
wherein, in (b), an effective value of power or an absolute value of DC voltage of the bias signal supplied to the substrate support in an (N+1)^{th} cycle (N is an integer of 1 or more) in (b-b) is greater than an effective value of power or an absolute value of DC voltage of the bias signal supplied to the substrate support in an N^{th} cycle in (b-b), and
an effective value of power or an absolute value of DC voltage of the bias signal supplied to the substrate support in (c-b) is equal to or greater than an effective value of power or the absolute value of DC voltage of the bias signal in (b-b).

(Appendix 2) The plasma processing method described in Appendix 1, wherein the substrate includes a mask film formed on the etching film such that the etching film is partially exposed, and
wherein, in (a), the etching film is etched by repeatedly executing, a plurality of times, a cycle including:
   (a-a) supplying a processing gas containing at least a carbon-containing gas into the chamber to generate plasma and forming a protective film at least on the mask film, and
   (a-b) supplying a processing gas containing at least a noble gas into the chamber to generate plasma and supplying a bias signal to the substrate support to etch at least a portion of the protective film and the etching film.

(Appendix 3) The plasma processing method described in Appendix 1 or, wherein the etching film is a silicon oxide film or a silicon nitride film.

(Appendix 4) The plasma processing method described in any one of Appendixes 1 to 3, wherein the dielectric film is a silicon nitride film or a silicon oxide film.

(Appendix 5) The plasma processing method described in any one of Appendixes 1 to 4, wherein the noble gas is argon (Ar) gas.

(Appendix 6) The plasma processing method described in any one of Appendixes 1 to 5, wherein, in (c), the cycle including (c-a) and (c-b) is repeated a plurality of times, and
an increment of the effective value of power or the absolute value of DC voltage of the bias signal in (b) is equal to an increment of the effective value of power or the absolute value of DC voltage of the bias signal in (c).

(Appendix 7) The plasma processing method described in any one of Appendixes 1 to 5, wherein, in (c), the cycle including (c-a) and (c-b) is repeated a plurality of times, and
an increment of the effective value of power or the absolute value of DC voltage of the bias signal in (b) is different from an increment of the effective value of power or the absolute value of DC voltage of the bias signal in (c).

(Appendix 8) The plasma processing method described in Appendix 7, wherein the increment in (c) is equal to or greater than zero.

(Appendix 9) The plasma processing method described in any one of Appendixes 1 to 5, wherein, in (c), the cycle including (c-a) and (c-b) is repeated a plurality of times, and
in (c), an effective value of power or an absolute value of DC voltage of the bias signal supplied to the substrate support in an (N+1)^{th} cycle (N is an integer of 1 or more) in (c-b) is smaller than an effective value of power or an absolute value of DC voltage of the bias signal supplied to the substrate support in an N^{th} cycle in (c-b).

(Appendix 10) The plasma processing method described in any one of Appendixes 6 to 9, wherein a number of times the cycle is repeated in (b) is less than a number of times the cycle is repeated in (c).

(Appendix 11) The plasma processing method described in any one of Appendixes 1 to 10, wherein, in (b-a) and (b-b), the plasma is generated using a source RF signal, and
an effective value of power of the source RF signal in (b-a) is greater than an effective value of power of the source RF signal in (b-b).

(Appendix 12) The plasma processing method described in Appendix 11, wherein each cycle in (b) includes an offset period between (b-a) and (b-b), and the source RF signal and the bias signal are continuously supplied during a period in which (b-a) is executed, the offset period, and a period in which (b-b) is executed.

(Appendix 13) The plasma processing method described in Appendix 12, wherein an effective value of power of the source RF signal during the offset period is smaller than an effective value of power of the source RF signal in (b-a), and an effective value of power or an absolute value of DC voltage of the bias signal during the offset period is smaller than an effective value of power or an absolute value of DC voltage of the bias signal in (b-b).

(Appendix 14) The plasma processing method described in Appendix 1 to Appendix 13, wherein, in (b-b), an etching rate of the etching film is higher than an etching rate of the dielectric film.

(Appendix 15) The plasma processing method described in any one of Appendixes 1 to 14, wherein an effective value of power or an absolute value of DC voltage of the bias signal in (b-b) continuously increases.

(Appendix 16) The plasma processing method described in any one of Appendixes 1 to 14, wherein an effective value of power or an absolute value of DC voltage of the bias signal in (b-b) continuously decreases.

(Appendix 17) A plasma processing apparatus comprising:
a chamber;
a substrate support disposed within the chamber; and
a controller configured to:
(a) prepare a substrate including an etching film and a dielectric film on the substrate support, the substrate having a first region where the etching film is exposed and a second region surrounding the first region, and the dielectric film being disposed in the second region;
(b) etch the etching film by repeatedly executing, a plurality of times, a cycle including:
   (b-a) supplying a processing gas containing at least a carbon-containing gas into the chamber to generate a plasma and forming a protective film at least on the dielectric film, and
   (b-b) supplying a processing gas containing at least a noble gas into the chamber to generate a plasma and supplying a bias signal to the substrate support to etch at least a portion of the protective film and the etching film;
(c) etch the etching film by executing, one or more times, a cycle including:
   (c-a) supplying a processing gas containing at least a carbon-containing gas into the chamber to generate a plasma and forming a protective film at least on the dielectric film, and
   (c-b) supplying a processing gas containing at least a noble gas into the chamber to generate a plasma and supplying a bias signal to the substrate support to etch at least a portion of the protective film and the etching film;
wherein, in (b), an effective value of power or an absolute value of DC voltage of the bias signal supplied to the substrate support in an (N+1)^{th} cycle (N is an integer of 1 or more) in (b-b) is greater than an effective value of power or an absolute value of DC voltage of the bias signal supplied to the substrate support in an N^{th} cycle in (b-b), and
an effective value of power or an absolute value of DC voltage of the bias signal supplied to the substrate support in (c-b) is equal to or greater than an effective value of power or an absolute value of DC voltage of the bias signal in (b-b).

According to an embodiment of the disclosure, it may be possible to provide an etching technique with a high selectivity ratio.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing method comprising:
(a) preparing a substrate including an etching film and a dielectric film disposed on a substrate support of a chamber provided in a plasma processing apparatus, the substrate including a first region where the etching film is exposed and a second region surrounding the first region, and the dielectric film being disposed in the second region;
(b) etching the etching film by repeatedly executing, a plurality of times, a cycle including:
(b-a) supplying a processing gas containing at least a carbon-containing gas into the chamber to generate a plasma and forming a protective film at least on the dielectric film, and
(b-b) supplying a processing gas containing at least a noble gas into the chamber to generate a plasma and supplying a bias signal to the substrate support to etch at least a portion of the protective film and the etching film; and
(c) etching the etching film by executing, one or more times, a cycle including:
(c-a) supplying a processing gas containing at least a carbon-containing gas into the chamber to generate a plasma and forming a protective film at least on the dielectric film, and
(c-b) supplying a processing gas containing at least a noble gas into the chamber to generate a plasma and supplying a bias signal to the substrate support to etch at least a portion of the protective film and the etching film,
wherein, in (b), an effective value of power or an absolute value of DC voltage of the bias signal supplied to the substrate support in an (N+1)^{th} cycle (N is an integer of 1 or more) in (b-b) is greater than an effective value of power or an absolute value of DC voltage of the bias signal supplied to the substrate support in an N^{th} cycle in (b-b), and
an effective value of power or an absolute value of DC voltage of the bias signal supplied to the substrate support in (c-b) is equal to or greater than an effective value of power or the absolute value of DC voltage of the bias signal in (b-b).

2. The plasma processing method according to claim 1, wherein the substrate includes a mask film formed on the etching film such that the etching film is partially exposed, and
in (a), the etching film is etched by repeatedly executing, a plurality of times, a cycle including:
(a-a) supplying a processing gas containing at least a carbon-containing gas into the chamber to generate plasma and forming a protective film at least on the mask film, and
(a-b) supplying a processing gas containing at least a noble gas into the chamber to generate plasma and supplying a bias signal to the substrate support to etch at least a portion of the protective film and the etching film.

3. The plasma processing method according to claim 1, wherein the etching film is a silicon oxide film or a silicon nitride film.

4. The plasma processing method according to claim 1, wherein the dielectric film is a silicon nitride film or a silicon oxide film.

5. The plasma processing method according to claim 1, wherein the noble gas is argon (Ar) gas.

6. The plasma processing method according to claim 1, wherein, in (c), the cycle including (c-a) and (c-b) is repeated a plurality of times, and
an increment of the effective value of power or the absolute value of DC voltage of the bias signal in (b) is equal to an increment of the effective value of power or the absolute value of DC voltage of the bias signal in (c).

7. The plasma processing method according to claim 1, wherein, in (c), the cycle including (c-a) and (c-b) is repeated a plurality of times, and
an increment of the effective value of power or the absolute value of DC voltage of the bias signal in (b) is different from an increment of the effective value of power or the absolute value of DC voltage of the bias signal in (c).

8. The plasma processing method according to claim 7, wherein the increment in (c) is equal to or greater than zero.

9. The plasma processing method according to claim 1, wherein, in (c), the cycle including (c-a) and (c-b) is repeated a plurality of times, and
in (c), an effective value of power or an absolute value of DC voltage of the bias signal supplied to the substrate support in an (N+1)^{th} cycle (N is an integer of 1 or more) in (c-b) is smaller than an effective value of power or an absolute value of DC voltage of the bias signal supplied to the substrate support in an N^{th} cycle in (c-b).

10. The plasma processing method according to claim 6, wherein a number of times the cycle is repeated in (b) is less than a number of times the cycle is repeated in (c).

11. The plasma processing method according to claim 1, wherein, in (b-a) and (b-b), the plasma is generated using a source RF signal, and
an effective value of power of the source RF signal in (b-a) is greater than an effective value of power of the source RF signal in (b-b).

12. The plasma processing method according to claim 11, wherein each cycle in (b) includes an offset period between (b-a) and (b-b), and the source RF signal and the bias signal are continuously supplied during a period in which (b-a) is executed, the offset period, and a period in which (b-b) is executed.

13. The plasma processing method according to claim 12, wherein an effective value of power of the source RF signal during the offset period is smaller than an effective value of power of the source RF signal in (b-a), and an effective value of power or an absolute value of DC voltage of the bias signal during the offset period is smaller than an effective value of power or an absolute value of DC voltage of the bias signal in (b-b).

14. The plasma processing method according to claim 1, wherein, in (b-b), an etching rate of the etching film is higher than an etching rate of the dielectric film.

15. The plasma processing method according to claim 1, wherein an effective value of power or an absolute value of DC voltage of the bias signal in (b-b) continuously increases.

16. The plasma processing method according to claim 1, wherein an effective value of power or an absolute value of DC voltage of the bias signal in (b-b) continuously decreases.

17. A plasma processing apparatus comprising:
a chamber;
a substrate support disposed within the chamber; and
a controller configured to:
(a) prepare a substrate including an etching film and a dielectric film on the substrate support, the substrate including a first region where the etching film is exposed and a second region surrounding the first region, and the dielectric film being disposed in the second region;
(b) etch the etching film by repeatedly executing, a plurality of times, a cycle including:
(b-a) supplying a processing gas containing at least a carbon-containing gas into the chamber to generate a plasma and forming a protective film at least on the dielectric film, and
(b-b) supplying a processing gas containing at least a noble gas into the chamber to generate a plasma and supplying a bias signal to the substrate support to etch at least a portion of the protective film and the etching film;
(c) etch the etching film by executing, one or more times, a cycle including:
(c-a) supplying a processing gas containing at least a carbon-containing gas into the chamber to generate a plasma and forming a protective film at least on the dielectric film, and
(c-b) supplying a processing gas containing at least a noble gas into the chamber to generate a plasma and supplying a bias signal to the substrate support to etch at least a portion of the protective film and the etching film;
wherein, in (b), an effective value of power or an absolute value of DC voltage of the bias signal supplied to the substrate support in an (N+1)^{th} cycle (N is an integer of 1 or more) in (b-b) is greater than an effective value of power or an absolute value of DC voltage of the bias signal supplied to the substrate support in an N^{th} cycle in (b-b), and
an effective value of power or an absolute value of DC voltage of the bias signal supplied to the substrate support in (c-b) is equal to or greater than an effective value of power or an absolute value of DC voltage of the bias signal in (b-b).
